(19) United States
(12) Patent Application Publication
(10) Pub. No.: US 2006/0083283 A1
(43) Pub. Date: Apr. 20, 2006

(54) Surface-emitting laser, method for manufacturing surface-emitting laser, device and electronic apparatus

(76) Inventor: Takayuki Kondo, Suwa (JP)

Correspondence Address: HARNESS, DICKEY & PIERCE, P.L.C., P.O. BOX 828, BLOOMFIELD HILLS, MI, 48303, US

(21) Appl. No.: 11/204,098

(22) Filed: Aug. 15, 2005

(30) Foreign Application Priority Data
Oct. 15, 2004 (JP) 2004-301566

(51) Int. Cl. H01S 5/00

(52) U.S. Cl. 372/50.124

(57) ABSTRACT

Surface-emitting lasers are provided that can reduce the laser emission angle. Methods for manufacturing the surface-emitting lasers, devices and electronic apparatuses are also provided. The surface-emitting laser has a lens layer formed from semiconductor having a lens shape, that is a component of a resonator of the surface-emitting laser, and a multilayer reflection film disposed on an upper layer of the lens layer.

### RELATED APPLICATIONS

This application claims priority to Japanese Patent Application No. 2004-301566 filed Oct. 15, 2004 which is hereby expressly incorporated by reference herein in its entirety.

### BACKGROUND

1. Technical Field

The present invention relates to surface-emitting lasers, methods for manufacturing surface-emitting lasers, devices and electronic apparatuses.

2. Related Art

Semiconductor lasers include edge-emitting lasers that emit a laser light at an edge of a semiconductor substrate, and surface-emitting lasers that emit a laser light from a surface of a semiconductor substrate. Surface-emitting lasers are characterized in that the laser emission angle is isotropic and small compared to edge-emitting lasers. When a surface-emitting laser is used as a light source for optical communications, for example, a large optical output is required. In order to increase the output of a surface-emitting laser, an enlargement of its laser emission aperture is effective. However, when the laser emission aperture is enlarged, the laser emission angle becomes larger. When the laser emission angle becomes larger, and for example, when the surface-emitting laser and an optical fiber are directly, optically coupled without a lens or the like, the optical coupling efficiency is lowered, and their mounting margin is reduced.

According to a conventional method to compose a smaller laser emission angle of a surface-emitting laser, an upper surface of a columnar section composing a resonator of the surface-emitting laser is formed into a convex lens shape (lens layer or contact layer). An emitted light of the surface-emitting laser is converged by the lens layer or the contact layer, whereby the laser emission angle becomes smaller (for example, see FIG. 1, FIG. 7, and FIG. 8 of Japanese Laid-open Patent Application 2000-76682).

However, we now understand that, in an actual surface-emitting laser, a certain mechanism, besides the convex lens function of the lens layer, may have a significant contribution to the mechanism of reducing the laser emission angle. More specifically, an interface between a convex lens shape of the lens layer and air also functions as a concave surface mirror, as viewed from within the surface-emitting laser. Reflected light from the concave surface mirror influences the optical density distribution in the active layer, which changes the transverse mode. We now understand that the action of the concave surface mirror to narrow the laser emission angle may be greater than the convergence action of the convex lens.

The present invention has been made in view of the circumstances described above, and its object is to provide surface-emitting lasers that can reduce the laser emission angle, methods for manufacturing the surface-emitting lasers, devices and electronic apparatuses.

Also, it is an object of the present invention to provide surface-emitting lasers having a concave surface mirror with a high index of reflection, methods for manufacturing the surface-emitting lasers, devices and electronic apparatuses.

Moreover, it is an object of the present invention to provide surface-emitting lasers that can reduce the laser emission angle by a concave surface mirror with a high index of reflection and can be readily manufactured, methods for manufacturing the surface-emitting lasers, devices and electronic apparatuses.

### SUMMARY

To achieve the objects described above, a surface-emitting laser in accordance with the present invention is characterized in comprising: a lens layer formed from semiconductor having a lens shape, that is a component of a resonator of the surface-emitting laser; and a multilayer reflection film disposed on an upper layer of the lens layer.

The present invention can be provided with a structure in which, for example, the lens layer is formed in a convex lens shape, and the multilayer reflection film is laminated on the convex lens shape. Then, as viewed from within the surface-emitting laser, the multilayer reflection film appears to be formed in a concave surface mirror. The multilayer reflection film can provide a higher index of reflection than that of a concave surface mirror that is formed at an interface between a lens layer and air in the conventional surface-emitting laser. Therefore, in the surface-emitting laser in accordance with the present invention, the multilayer reflection film can cause a greater influence on the optical density distribution at the active layer than the conventional structure. Accordingly, the surface-emitting laser in accordance with the present invention can more effectively control the transverse mode, and reduce the laser emission angle.

Also, according to the present invention, the lens layer is formed from semiconductor, and therefore the lens layer can be readily formed into a lens shape by applying an etching treatment thereto. In this instance, by conducting isotropic etching by using a resist mask in a lens shape, the center of the columnar section composing the resonator (the optical axis of laser) and the optical axis of the lens section (the concave surface mirror) can be made coincident with each other in a self-alignment manner. Therefore, according to the present invention, a surface-emitting laser with high performance that can readily be manufactured can be provided.

Moreover, in accordance with the present invention, because the lens layer is formed from semiconductor, an electrode contact can be made at an upper surface (or a lower surface) of the lens layer. Accordingly, for example, even when the outer diameter of the lens layer and the outer diameter of the columnar section composing the resonator coincide with each other, an upper electrode in a ring shape can be readily formed along the circumference of the lens layer. Therefore, a part of the lens layer does not need to be removed for forming a contact of the upper electrode, such that a surface-emitting laser that can be formed with a simple manufacturing process can be provided.

Also, in accordance with the present invention, because the lens layer is formed from semiconductor, the lens layer is composed of a material similar to that of the columnar section of the resonator. Consequently, a refractive index difference between the lens layer and its lower layer becomes smaller, such that the effect of the concave surface mirror on an upper surface of the lens layer can be made more significant. This is because the reflection as viewed from within the resonator is composed by the concave surface mirror at the upper surface of the lens layer and the plane mirror at the lower surface of the lens layer, such that the smaller the contribution of the plane mirror, the greater the effect of the concave surface mirror becomes. In other words, when the refractive index difference at an interface between the lens layer and the columnar section of the resonator is smaller, the rate of reflection at the plane surface (the lower surface) of the lens layer becomes smaller, and the effect of the concave surface mirror formed at the upper surface of the lens layer can be increased. In other words, even when the upper surface of the lens layer is provided with a gentler curve, a sufficient concave surface mirror effect can be obtained, and the laser emission angle can be sufficiently reduced.

Also, a surface-emitting laser in accordance with the present invention may preferably have: a lower DBR defining a distributed reflection type multilayer mirror; an active layer; a current aperture layer (oxidation constricting layer) defining a flow area of a current; an upper DBR defining a distributed reflection type multilayer mirror; a lens layer formed from semiconductor having a lens shape; and a multilayer reflection film disposed on an upper layer of the lens layer.

According to the present invention, the resonator can be formed with a structure in which the lower DBR, the active layer, the current aperture layer, the upper DBR, the lens layer and the multilayer reflection film are successively laminated. It is noted here that the multilayer reflection film can form a concave surface mirror with a higher index of reflection than that of a concave surface mirror that is formed at an interface between a lens layer of a conventional surface-emitting laser and air. Therefore, the surface-emitting laser of the present invention can provide, due to the multilayer reflection film, a greater influence on the optical density distribution at the active layer than that of the conventional surface-emitting laser, more effectively control the transverse mode, and reduce the laser emission angle.

Also, in accordance with the present invention, because the lens layer is formed from semiconductor, a surface-emitting laser that exhibits a high performance and yet can be formed with a simple manufacturing process can be provided. Also, in accordance with the present invention, because the lens layer is formed from semiconductor, a part of the lens layer does not need to be removed for forming a contact of the upper electrode, such that a surface-emitting laser that can be formed with a simple manufacturing process can be provided. Moreover, in accordance with the present invention, because the lens layer is formed from semiconductor, the effect of the concave surface mirror formed at the upper surface of the lens layer can be increased, such that a sufficient concave surface mirror effect can be obtained even when the upper surface of the lens layer is provided with a gentler curve, and the laser emission angle can be sufficiently reduced.

Also, according to the surface-emitting laser of the present invention, for example, as the number of layers in the upper DBR, 0-20 cycles can be used. In other words, it is possible to provide a structure in which the upper DBR is cancelled, and the function of the upper DBR is borne by the lens layer and the multilayer reflection film.

Also, in the surface-emitting laser in accordance with the present invention, the multilayer reflection film may preferably be formed from multilayer dielectric films.

According to the present invention, because the refractive index of dielectric is higher than the refractive index of semiconductor, the index of reflection at the multilayer reflection film can be increased. Accordingly, the laser emission angle can be further reduced. The multilayer reflection film composed of dielectric can be composed of a combination of materials that are generally used for optical films. For example, the multilayer reflection film can be composed of a combination of TiO₂, Ta₂O₅, α-Si and SiO₂.

Furthermore, in the surface-emitting laser in accordance with the present invention, the multilayer reflection film may preferably be formed from multilayer semiconductor films.

The multilayer reflection film of the present invention can be readily formed by using an etching treatment. Accordingly, in accordance with the present invention, it is possible to provide a surface-emitting laser that exhibits a high performance and can be readily manufactured. Also, in accordance with the present invention, because the multilayer reflection film is formed from semiconductor, it is possible to provide a structure in which an upper electrode is in contact with the multilayer reflection film.

Also, in the surface-emitting laser in accordance with the present invention, the lens layer may preferably be disposed on an upper layer of the upper DBR and have a convex lens shape; on an outer circumference neighboring portion of the lens layer, an upper electrode that is electrically connected to the outer circumference neighboring portion may preferably be disposed; and the multilayer reflection film may preferably be disposed to cover an exposed portion of the lens layer and at least a portion of the upper electrode.

In accordance with the present invention, as viewed from within the surface-emitting laser, the multilayer reflection film appears to be formed in a concave surface mirror. The multilayer reflection film can give a greater influence on the optical density distribution at the active layer than a conventional surface-emitting laser. Accordingly, the surface-emitting laser in accordance with the present invention can more effectively control the transverse mode, and reduce the laser emission angle.

Moreover, in accordance with the present invention, because the lens layer is formed from semiconductor, the lens layer can be readily formed into a desired shape, and a surface-emitting laser that exhibits a high performance and yet can be formed with a simple manufacturing process can be provided. Also, in accordance with the present invention, because the lens layer is formed from semiconductor, there is no need to provide a structure in which, for example, an upper electrode is connected to the upper DBR by removing a part of the lens layer, such that a surface-emitting laser that can be formed with a simple manufacturing process can be provided. Moreover, in accordance with the present invention, because the lens layer is formed from semiconductor, the effect of the concave surface mirror formed at the upper surface of the lens layer can be increased, such that a sufficient concave surface mirror effect can be obtained even when the upper surface of the lens layer is provided with a gentler curve, and the laser emission angle can be sufficiently reduced.

Also, in the surface-emitting laser in accordance with the present invention, the lens layer may preferably be disposed on an upper layer of the upper DBR and have a convex lens shape; the multilayer reflection film may preferably be disposed on an upper layer of the lens layer; and on an outer circumference neighboring portion of the multilayer reflection film, an upper electrode that is electrically connected to the outer circumference neighboring portion may preferably be disposed.

According to the present invention, the multilayer reflection film can effectively control the transverse mode, and can reduce the laser emission angle.

Moreover, in accordance with the present invention, because the lens layer is formed from semiconductor, the lens layer can be readily formed into a desired shape, and a surface-emitting laser that exhibits a high performance and yet can be formed with a simple manufacturing process can be provided. Also, in accordance with the present invention, because the multilayer reflection film is formed from semiconductor, a contact between the multilayer reflection film and an upper electrode can be readily made, and a surface-emitting laser that can be formed with a simple manufacturing process can be provided.

Also, in the surface-emitting laser in accordance with the present invention, the lens layer may preferably be in a convex lens shape whose apex portion is flat.

According to the present invention, the apex portion of the lens layer is flat, such that there is no need to conduct an etching treatment or the like for the apex portion. Therefore, according to the present invention, the dimension (length) of the resonator at its center axis can be readily provided with a high accuracy. Therefore, in accordance with the present invention, the index of reflection of the resonator at its center axis, which is most important for the surface-emitting laser to exhibit its functions, can be readily set to a desired value. Therefore, in the surface-emitting laser according to the present invention, basic laser characteristics such as the threshold value, efficiency and the like can be excellently and readily obtained.

Also, in accordance with the present invention, light emitted from portions of the resonator removed from its center axis can receive the concave surface mirror effect of the multilayer reflection film that is laminated on the upper layer of the curved surface portion (convex lens shape portion) of the lens layer. Therefore, in accordance with the present invention, a sufficient beam re-shaping effect as a whole can be obtained, and the laser emission angle can be sufficiently made smaller.

Also, in the surface-emitting laser in accordance with the present invention, the lens layer may preferably have a convex lens shape, and a bottom surface of the convex lens shape may preferably be smaller than an upper surface of a columnar section composing a part of the resonator of the surface-emitting laser.

According to the present invention, the lens shaped portion (lens layer) is provided on a portion of the upper surface of the columnar section. Therefore, the convex lens shape can be formed with a smaller curvature. Accordingly, the laser emission angle reducing effect of the multilayer reflection film disposed on the upper layer of the lens layer can be further increased. Therefore, in accordance with the present invention, the lens layer can be made thinner, and a surface-emitting laser with a higher performance can be readily provided.

Also, in the surface-emitting laser in accordance with the present invention, a dielectric film (embedding layer) may preferably be arranged around the columnar section that forms at least a part of the resonator.

In accordance with the present invention, for example, short-circuit of an electrode (for example, an upper electrode) disposed on the emission surface of the resonator with another semiconductor portion can be avoided by the dielectric film. Also, a step difference between the upper surface and the side surface of the columnar section of the resonator can be eliminated by the dielectric film. By this, an upper electrode that connects to the lens layer can be formed on a smooth plane surface or curved surface without steps, and such an upper electrode can be excellently and readily formed. It is noted that the dielectric film can be composed of, for example, polyimide.

To achieve the objects described above, a device in accordance with the present invention is characterized in comprising the surface-emitting laser described above.

In accordance with the present invention, there can be provided a device equipped with a surface-emitting laser that can sufficiently reduce the laser emission angle and can be readily manufactured.

To achieve the objects described above, a method for manufacturing a surface-emitting laser in accordance with the present invention is characterized in comprising: forming at least a plurality of semiconductor layers on a semiconductor substrate to form a semiconductor laminated body that is a component of a resonator of the surface-emitting laser; forming a resist layer having a lens shape on the semiconductor laminated body; forming a columnar section that becomes a part of the resonator and bringing an upper surface of the columnar section in a lens shape in relief by conducting an etching treatment using the resist layer as a mask; and forming a multilayer reflection film on an upper surface of the columnar section in a lens shape.

According to the present invention, the lens layer is formed from semiconductor, and therefore the lens layer can be readily formed into a lens shape by applying an etching treatment or the like thereto. In this instance, by conducting isotropic etching by using a resist mask in a lens shape, the center of the columnar section composing the resonator (the optical axis of laser) and the optical axis of the lens section (the concave surface mirror) can be made coincident with each other in a self-alignment manner. Therefore, according to the present invention, a surface-emitting laser with a high performance can readily be manufactured.

Moreover, in accordance with the present invention, the multilayer reflection film is formed on the upper layer of the lens layer in a lens shape, such that a surface-emitting laser that can reduce the laser emission angle more than conventional art can be readily manufactured.

Also, the step of forming the semiconductor laminated body in accordance with the present invention may preferably include a step of forming a lower DBR layer on a semiconductor substrate, a step of forming an active layer on the lower DBR layer, and a step of forming an upper DBR layer on the active layer.

Also, in the method for manufacturing a semiconductor layer in accordance with the present invention, an upper electrode in a ring shape may preferably be formed on an outer circumference neighboring portion of the upper surface of the columnar section in a lens shape formed by the etching treatment, and then the multilayer reflection film may preferably be formed to cover at least an exposed portion in the upper surface of the columnar section in a lens shape.

According to the present invention, the lens layer can be formed from semiconductor (a part of the semiconductor laminated body), and an upper electrode can be brought in contact with an outer circumference of the lens layer. Therefore, the upper electrode can be readily formed. Then, by forming the multilayer reflection film in a manner to cover an exposed portion of the lens layer, a surface-emitting laser that can further reduce the laser emission angle than conventional art can be readily manufactured.

Also, in the method for manufacturing a surface-emitting laser in accordance with the present invention, an upper electrode in a ring shape may preferably be formed on an outer circumference neighboring portion of an upper surface of the multilayer reflection film after the multilayer reflection film is formed.

According to the present invention, the multilayer reflection film can be formed from semiconductor, and an upper electrode can be brought in contact with an outer circumference of the multilayer reflection film. Therefore, a surface-emitting laser in which an upper electrode can be readily formed, and the laser emission angle can be reduced more than conventional art can be readily manufactured.

Moreover, in the method for manufacturing a surface-emitting laser in accordance with the present invention, the etching treatment may preferably include dry etching with a high selection ratio that hardly etches the resist layer but etches the semiconductor laminated body to thereby form the columnar section, and dry etching with a low selection ratio that etches the resist layer and the semiconductor laminated body at the same time to thereby form an upper surface of the columnar section in a lens shape in relief.

According to the present invention, by the dry etching with a high selection ratio, while leaving the resist layer remained almost as it is, the columnar section (a part of the resonator) with a large side surface angle can be formed. Further, by the dry etching with a low selection ratio, the upper surface of the columnar section (light emission surface) including the resist layer can be formed in a lens shape in relief, and the lens layer in a convex lens shape can be disposed on the upper surface of the columnar section.

According to the present invention, the apex portion of the lens shape (in other words, the portion adjacent to the center axis of the lens layer) is not etched. By this, the original design film thickness defining the dimension of the resonator at its center axis can be retained. Accordingly, the index of reflection of the resonator at its center axis, which is most important for the surface-emitting laser, can be readily set to a desired value. Therefore, according to the present invention, a surface-emitting laser that exhibits basic laser characteristics such as the threshold value, efficiency and the like to a high degree can be excellently and readily manufactured.

Also, in accordance with the present invention, light emitted from portions of the resonator removed from its center axis can be reflected by a concave surface mirror defined by the multilayer reflection film. Therefore, a surface-emitting laser that exhibits basic laser characteristics to a high degree and can reduce the laser emission angle more than conventional art can be excellently and readily manufactured.

Also, the step of forming the semiconductor laminated body in accordance with the present invention may preferably include a step of forming a lower DBR layer on the semiconductor substrate, a step of forming an active layer on the lower DBR layer, and a step of forming an upper DBR layer on the active layer.

To achieve the objects described above, an electronic apparatus in accordance with the present invention is characterized in comprising the surface-emitting laser described above or the device described above.

According to the present invention, there can be provided an electronic apparatus equipped with a surface-emitting laser that can reduce the laser emission angle more than conventional art.

### BRIEF DESCRIPTION OF THE DRAWINGS

FIG. 1 is a schematic cross-sectional view of a surface-emitting laser in accordance with a first embodiment of the present invention.

FIGS. 2(a)-(d) are cross-sectional views indicating a method for manufacturing a surface-emitting laser in accordance with the same embodiment.

FIGS. 3(a)-(d) are cross-sectional views indicating the method for manufacturing a surface-emitting laser in accordance with the same embodiment.

FIG. 4 is a cross-sectional view indicating a surface-emitting laser in accordance with a second embodiment of the present invention.

FIG. 5 is a cross-sectional view indicating a surface-emitting laser in accordance with a third embodiment of the present invention.

FIG. 6 is a cross-sectional view indicating a surface-emitting laser in accordance with a fourth embodiment of the present invention.

### DETAILED DESCRIPTION

Surface-emitting lasers in accordance with embodiments of the present invention are described below with reference to the accompanying drawings.

### FIRST EMBODIMENT

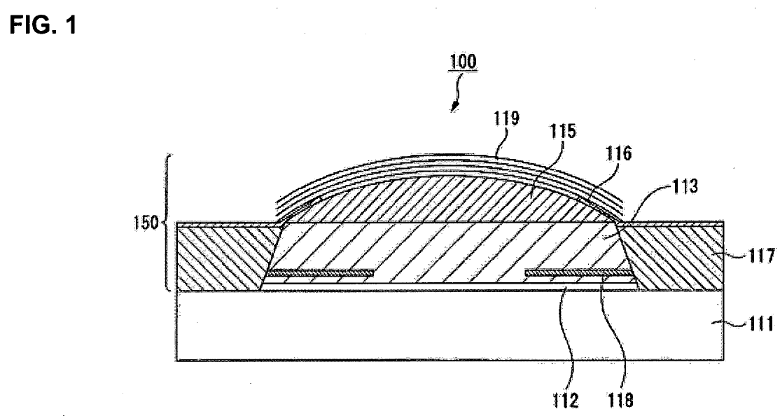

FIG. 1 is a schematic cross-sectional view showing an example of a surface-emitting laser in accordance with a first embodiment of the present invention. The surface-emitting laser 100 shown in FIG. 1 is formed from a lower DBR 111, an active layer 112, an upper DBR 113, a lens layer 115, an upper electrode 116, an embedding layer 117, an oxidation constricting layer (current aperture layer) 118, and a multilayer reflection film 119.

The lower DBR 111 is provided on, for example, an n-type GaAs substrate (not shown). The lower DBR 111 is composed of a distributed reflection type multilayer mirror (DBR mirror) of 30 pairs (cycles) of alternately laminated, for example, “GaAs” and “AlGaAs” layers. The active layer 112 is provided on the lower DBR 111. The active layer 112 is formed from, for example, an InGaAs quantum well. Furthermore, the oscillation wavelength of the active layer 112 may be, for example, 970 nm.

The upper DBR 113 is provided on the active layer 112. The upper DBR 113 of the present embodiment may preferably be formed from semiconductor. For example, the upper DBR 113 is composed of a distributed reflection type multilayer mirror (DBR mirror) of, for example, 10 pairs (cycles) of alternately laminated “GaAs” and “AlGaAs” layers.

Also, the number of pairs (cycles) of the upper DBR 113 may be selected within the range between 0 and 20 depending on each design. In this case, the number of layers (the number of pairs) of the multilayer reflection film 119 may be set according to the number of pairs of the upper DBR 113, whereby a desired index of reflection of a resonator as a whole can be obtained.

The lower DBR 111 is doped to be n-type semiconductor. The upper DBR 113 is doped to be p-type semiconductor. The active layer 112 is not doped with an impurity. Accordingly, the lower DBR 111, the active layer 112 and the upper DBR 113 form a pin diode, thereby composing a resonator of the surface-emitting laser. The active layer 112 and the upper DBR 113 in the resonator compose a columnar section 150 formed in a convex shape over an upper surface of the lower DBR 111 and the semiconductor substrate. It is noted that the lower DBR 111 may also be formed in a convex shape, and a portion of the lower DBR 11 adjacent to its upper surface can be a part of the columnar section 150. The upper surface and the lower surface of the columnar section 150 define emission surfaces of a laser light of the surface-emitting laser 100.

The oxidation constricting layer 118 is formed in a ring shape in the upper DBR 113. The oxidation constricting layer 118 may be formed through, for example, oxidizing an AlAs layer in a ring shape with water vapor to form an aluminum oxide layer (dielectric layer). In other words, the oxidation constricting layer 118 has a plane configuration in a ring shape, and the center of the ring shape is arranged on the center axis (emission axis) of the surface-emitting laser 100. Then, the oxidation constricting layer 118 defines a flow area of a current that flows in the resonator of the surface-emitting laser 100. Accordingly, the oxidation constricting layer 118 acts to reduce the area of the active region that emits light, lower the threshold current, and narrow the beam width.

The lens layer 115 is provided on an upper surface of the upper DBR 113. Therefore, the lens layer 115 is provided on one end portion (light emission surface) of the surface-emitting laser 100. Also, the lens layer 115 functions as a part of the upper DBR 113, and composes a part of the columnar section 150. The lens layer 115 is formed from semiconductor. For example the lens layer 115 may be formed from GaAs. The curvature of the upper surface of the lens layer 115 may be, for example, 300 μm.

The embedding layer (dielectric film) 117 is disposed to cover side surfaces of the active layer 112 and the upper DBR 113 and an upper surface of the lower DBR 111. The embedding layer 117 may be formed from polyimide resin, benzocyclobutene (BCB), silicon modified polyimide resin, epoxy resin, silicon modified epoxy resin, acrylic resin, phenol resin, polybenzoxazole (PBO) or the like.

The upper electrode 116 is in a ring shape, and is disposed on an area adjacent to the outer circumference of the lens layer 115 and on the embedding layer 117. Further, the upper electrode 116 is in ohmic contact with the lens layer 115. Also, the surface-emitting laser 100 is equipped with a lower electrode (not shown) that is in ohmic contact with the lower DBR 111. The lower electrode is provided, for example, over the entire bottom surface of the lower DBR 111.

The multilayer reflection film 119 is provided on an upper layer of the lens layer 115. Also, the multilayer reflection film 119 is disposed to cover a part of the upper electrode 116. The multilayer reflection film 119 functions as a part of the upper DBR 113, and composes a part of the columnar section 150. Also, the multilayer reflection film 119 may be formed as, for example, a dielectric multilayer film. In this case, the multilayer reflection film 119 may be composed of a distributed reflection type multilayer mirror (DBR mirror) of 4 pairs (cycles) of alternately laminated, for example, “TiO₂” and “SiO₂” layers.

The dielectric multilayer film can be composed of a combination of materials that are generally used as optical films. The multilayer reflection film 119 can be composed of a combination of TiO₂, Ta₂O₅, α-Si and SiO₂.

A voltage is applied across the upper electrode 116 and the lower electrode in the surface-emitting laser 100 thus structured, such that a potential in a forward direction is impressed to the pin diode. Then, recombinations of electrons and holes occur in the active layer 112, thereby causing emission of light due to the recombinations. Stimulated emission occurs during the period the generated light reciprocates between the upper DBR 113 and the lower DBR 111 through the oxidation constricting aperture (aperture in a ring shape) of the oxidation constricting film 118, whereby the light intensity is amplified. When the optical gain exceeds the optical loss, laser oscillation occurs, whereby a laser light is emitted from an aperture section of the upper electrode 116 in a direction orthogonal to the substrate.

Also, the multilayer reflection film 119 functions as a concave surface mirror, as viewed from within the surface-emitting laser 100. Therefore a major portion of the laser light within the surface-emitting laser 100 is reflected by the multilayer reflection film 119, and the remaining portion of the laser light is emitted outside of the surface-emitting laser 100.

According to the above, in the surface-emitting laser 100 in accordance with the present embodiment, the multilayer reflection film 119 is provided with a higher index of reflection than an index of reflection of a concave surface mirror formed at an interface between a lens layer of a conventional surface-emitting laser and air. Accordingly, in the surface-emitting laser 100, the multilayer reflection film 119 can cause a greater influence on the optical density distribution at the active layer 112 than the conventional surface-emitting laser. Accordingly, the surface-emitting laser 100 can more effectively control the transverse mode, and reduce the laser emission angle.

Also, in the surface-emitting laser 100 in accordance with the present embodiment, the lens layer 115 is formed from semiconductor, and therefore the lens layer 115 can be readily formed into a lens shape by applying an etching treatment thereto. In this instance, by conducting isotropic etching by using a resist mask in a lens shape, the center of the columnar section 150 composing the resonator (the optical axis of laser) and the optical axis of the lens section can coincide with each other in a self-alignment manner. Therefore, according to the present invention, the surface-emitting laser 100 which has a high performance but can readily be manufactured can be provided.

Moreover, in the surface-emitting laser 100, because the lens layer 115 is formed from semiconductor, an electrode contact can be made at an upper surface (or a lower surface) of the lens layer 115. Accordingly, for example, even when the outer diameter of the lens layer 115 and the outer diameter of the columnar section 150 composing the resonator coincide with each other (in a structure in which the upper DBR 113 is not exposed), the upper electrode 116 in a ring shape can be readily formed along the circumference of the lens layer 115. Therefore, a part of the lens layer 115 does not need to be removed for forming a contact of the upper electrode 116, such that it is possible to provide a surface-emitting laser 100 that can be formed with a simple manufacturing process.

Also, in the surface-emitting laser 100, because the lens layer 115 is formed from semiconductor, the lens layer 115 is composed of a material similar to that of the columnar section 150 (the upper DBR 113 and the like) of the resonator. Consequently, a refractive index difference between the lens layer 115 and its lower layer, i.e., the upper DBR 113 becomes smaller, such that the effect of the concave surface mirror on the upper surface of the lens layer 115 can be made more significant. This is because the reflection as viewed from within the resonator is composed by the concave surface mirror at the upper surface of the lens layer 115 and the plane mirror at the lower surface of the lens layer 115, such that the smaller the contribution of the plane mirror, the greater the effect of the concave surface mirror becomes. In other words, when the refractive index difference at an interface between the lens layer 115 and the columnar section 150 of the resonator is smaller, the rate of reflection at the lower surface of the lens layer 115 becomes smaller, and the effect of the concave surface mirror formed at the upper surface of the lens layer 115 can be increased. In other words, even when the upper surface of the lens layer 115 is provided with a gentler curve, a sufficient concave surface mirror effect can be obtained, and the laser emission angle can be sufficiently reduced.

The surface-emitting laser 100 in accordance with the present embodiment was actually manufactured, and its characteristics were measured. In this instance, the fundamental transverse mode oscillation up to the maximum output of 5 mW was confirmed. Further, FWHM (full width at half maximum) of the emission angle of the laser was 10 degrees.

Manufacturing Method

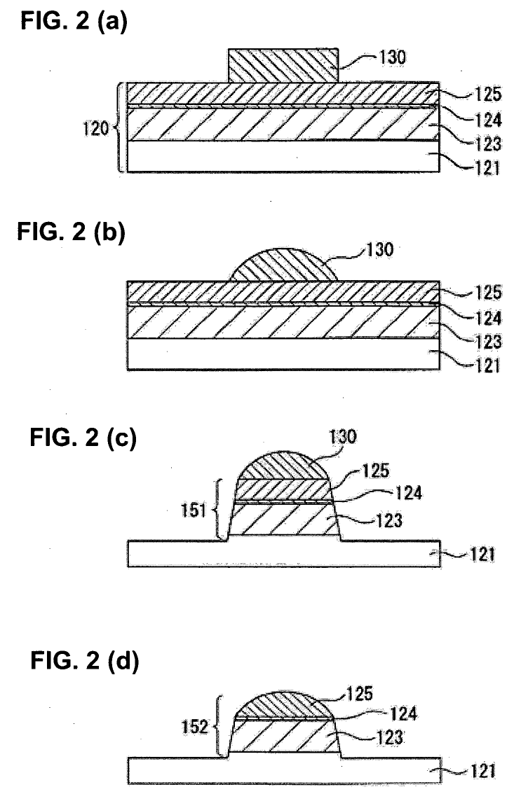

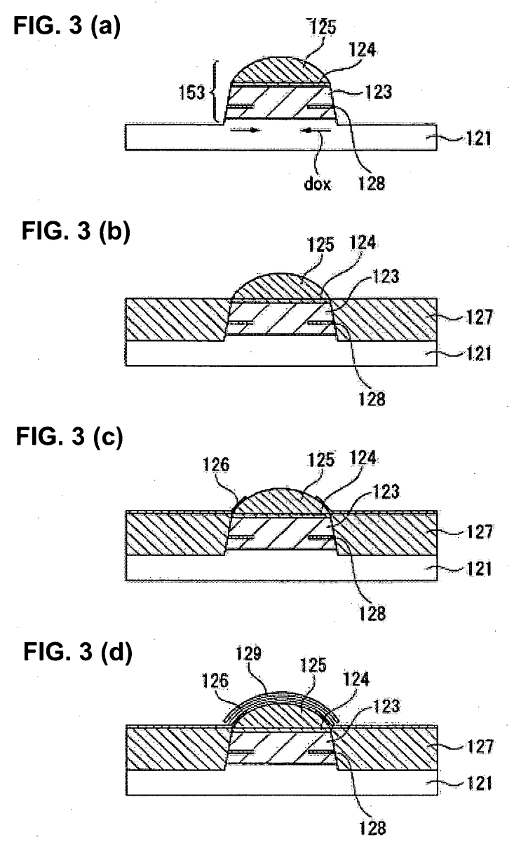

Next, a method for manufacturing the surface-emitting laser 100 having the structure described above is described with reference to FIGS. 2 to FIG. 3.

First Step

FIG. 2 (a) is a schematic cross-sectional view showing a first step in the present manufacturing method. First, a lower DBR layer 121 composed of a distributed reflection type multilayer mirror having 30 pairs of alternately laminated GaAs and AlGaAs layers is formed on, for example, an n-type GaAs substrate (not shown). It is noted here that the lower DBR layer 121 is made to be n-type semiconductor by doping. The lower DBR layer 121 corresponds to the lower DBR 111 in FIG. 1. Next, on the lower DBR layer 121 is formed an active layer (not shown) composed of an InGaAs quantum well. The active layer is a source of the active layer 112 in FIG. 1. The oscillation wavelength of the active layer is, for example, 970 nm.

Further, on the active layer is formed an upper DBR layer 123 composed of a distributed reflection type multilayer mirror having 10 pairs of alternately laminated GaAs and AlGaAs layers. It is noted here that the upper DBR layer 123 is made to be p-type semiconductor by doping. The upper DBR layer 123 is a source of the upper DBR 113 in FIG. 1. Then, a lens layer 125 is formed on a contact layer 124. The lens layer 125 may be composed of semiconductor having a bandgap greater than a bandgap corresponding to the energy of a laser light of the surface-emitting laser 100. For example, the lens layer 125 is composed of GaAs. The lens layer 125 is a source of the lens layer 115 in FIG. 1.

Epitaxial layers 120 composed of the lower DBR layer 121, the active layer, the upper DBR layer 123, the contact layer 124 and the lens layer 125 can be epitaxially grown by a metal organic vapor phase growth (MOVPE: Metal-Organic Vapor Phase Epitaxy) method. In this instance, for example, the growth temperature may be 750° C., the growth pressure may be 2×10⁴ Pa, organic metals such as TMGa (trimethyl gallium) and TMAl (trimethyl aluminum) may be used as III-group material, AsH₃ may be used as V-group material, H₂Se may be used as n-type dopant, and DEZn (dimethyl zinc) may be used as p-type dopant. The epitaxial layers 120 compose a semiconductor laminated body that is a component of a resonator of the surface-emitting laser.

Next, a photoresist is coated on the lens layer 125, and then the photoresist is patterned by photolithography. By this, a resist layer 130 having a predetermined pattern is formed, as shown in FIG. 2 (a).

Second Step

FIG. 2 (b) is a schematic cross-sectional view showing a second step of the present manufacturing method. In this step, the resist layer 130 is formed into a convex lens shape. Concretely, the resist layer 130 is heated and re-flowed, in other words, melted resist is flowed and re-formed. By this, the resist layer 130 is influenced by surface tension and is transformed into a convex lens shape shown in FIG. 2 (b). The heating method can be conducted by using, for example, a hot plate, a heated air circulation type oven or the like. Conditions when a hot plate is used may differ depending on the material quality of the resist, and may be 2-10 minutes, and more preferably be 5 minutes at 150° C. or higher. Also, in the case of a heated air circulation type oven, it may preferably be 20-30 minutes at 160° C. or higher. It is noted that the resist layer 130 may be formed into a convex lens shape by using a gray mask, without heating.

Third Step

FIG. 2 (c) is a schematic cross-sectional view showing a third step of the present manufacturing method. In this step, as shown in FIG. 2 (c), a columnar section 151 composed of the upper DBR layer 123, the contact layer 124 and the lens layer 125 is formed. The columnar section 151 defines a part of the resonator. It is noted that a part of the lower DBR 121 and the active layer may define a part of the columnar section 151. To form the columnar section 151, the resist layer 130 in a convex lens shape is used as a mask, and dry-etching with a high selection ratio is conducted. In other words, while the resist layer 130 is almost entirely left as it is, the lens layer 125, the contact layer 124, the upper DBR 123, the active layer and up to an upper portion of the lower DBR 121 are etched in a mesa shape, thereby forming the columnar section 151. The selection ratio at this etching may preferably be 2.0 or greater, for example. By this step, the columnar section 151 having a great side surface angle can be formed.

Fourth Step

FIG. 2 (d) is a schematic cross-sectional view showing a fourth step of the present manufacturing method. In this step, the columnar section 151 and the resist layer 130 are isotropically etched until the resist layer 130 disappears. In other words, dry etching with a low selection ratio condition is conducted. By so doing, the columnar section 151 and the resist layer 130 are etched concurrently, whereby the lens shape of the resist layer 130 is formed in relief on the upper surface of the columnar section 151, and a columnar section 152 having a lens shape on its upper surface (one end portion) is formed.

Fifth Step

FIG. 3 (a) is a schematic cross-sectional view showing a fifth step of the present manufacturing method. In this step, an oxidation constricting layer 128 is formed. For example, by conducting a water vapor processing at 400° C., an AlAs layer in the upper DBR layer 123 is oxidized by water vapor in a ring shape from the outer side of the columnar section 152. By this, the AlAs becomes aluminum oxide, and a columnar section 153 having the oxidation constricting layer 128 in a ring shape is formed. The oxidation constricting layer 128 corresponds to the oxidation constricting film 118 in FIG. 1.

Sixth Step

FIG. 3 (b) is a schematic cross-sectional view showing a sixth step of the present manufacturing method. In this step, an embedding layer (dielectric layer) 127 is formed around a part of the lower DBR layer 121, the active layer, the upper DBR layer 123 and the contact layer 124. Concretely, a dielectric film is embedded around the columnar section 153 up to a height adjacent to the contact layer 124 in the columnar section 153, to thereby form the embedding layer 127. As the constituent material of the embedding layer 127, for example, polyimide or BCB may be used. For example, polyimide in a liquid state may be coated around the columnar section 153 by a droplet ejection method, and then the polyimide is hardened by sintering or the like. By this, the embedding layer 127 can be readily formed. By forming the embedding layer 127, an upper electrode 126 to be formed in a later step can be prevented from becoming short-circuited with undesired portions. Also, the embedding layer 127 planarizes the circumference of the columnar section 153, such that formation of the upper electrode 126 becomes easier. The embedding layer 127 corresponds to the embedding layer 117 in FIG. 1.

Seventh Step

FIG. 3 (c) is a schematic cross-sectional view showing a seventh step of the present manufacturing method. In this step, an upper electrode 126 that is in ohmic contact with the lens layer 125 is formed. Concretely, the upper electrode 126 in a ring shape is formed on the lens layer 125 in an area adjacent to its outer circumference and on the embedding layer 127. Here, the upper electrode 126 is brought in ohmic contact with the lens layer 125. The upper electrode 126 can be formed through, for example, forming an Au—Ge alloy film by a vacuum vapor deposition method, and patterning the alloy film by etching. The upper electrode 126 corresponds to the upper electrode 116 in FIG. 1.

Eighth Step

FIG. 3 (d) is a schematic cross-sectional view showing an eighth step of the present manufacturing method. In this step, a dielectric multilayer reflection film 129 is formed on an upper surface of the lens layer 125. Concretely, for example, an ion assisted vapor deposition apparatus and a mask vapor deposition apparatus are used to form a DBR of 4 cycles of TiO₂/SiO₂ layers, with a designed wavelength of 970 nm, thereby forming the dielectric multilayer reflection film 129. The dielectric multilayer reflection film 129 may also be formed in a manner to cover a part of the upper electrode 126, as shown in FIG. 3 (d). The dielectric multilayer reflection film 129 corresponds to the multilayer reflection film 119 in FIG. 1.

After this step, a lower electrode (not shown) that is in ohmic contact with the lower DBR 121 is formed, whereby the surface-emitting laser 100 shown in FIG. 1 is completed. It is noted that the lower electrode can be formed in a manner similar to the upper electrode 126.

According to the above, in accordance with the present manufacturing method, the lens layer 125 is formed from semiconductor, and therefore the lens layer 125 can be readily formed into a lens shape by applying an etching treatment or the like thereto. In this instance, by conducting isotropic etching by using a resist mask in a lens shape, the center of the columnar section 153 composing the resonator (the optical axis of laser) and the optical axis of the lens section (the concave surface mirror) can be made coincident with each other. Therefore, according to the present manufacturing method, a high performance surface-emitting laser 100 can readily be manufactured. Also, in accordance with the present manufacturing method, the dielectric multilayer reflection film 129 is formed on an upper layer of the lens layer 125 that is formed in a lens shape, such that a surface-emitting laser 100 that can reduce the laser emission angle more than conventional art can be readily manufactured.

### SECOND EMBODIMENT

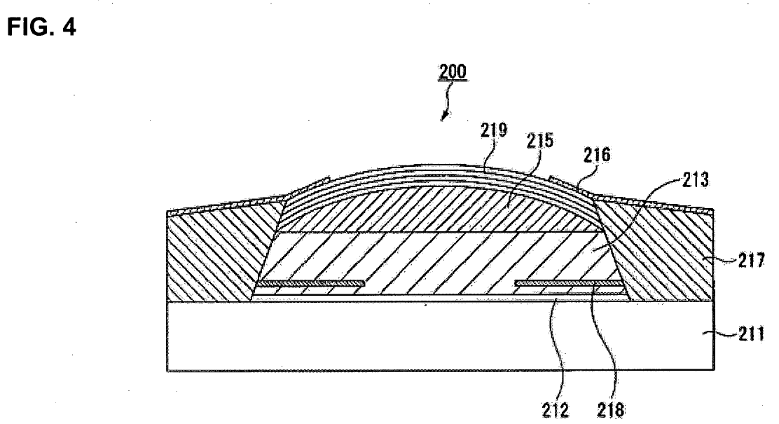

FIG. 4 is a schematic cross-sectional view showing one example of a surface-emitting laser in accordance with a second embodiment of the present invention. A main difference between the surface-emitting laser 200 of the present embodiment and the surface-emitting laser 100 of the first embodiment is that an upper electrode 216 is electrically connected to a multilayer reflection film 219, and the multilayer reflection film 219 is formed from semiconductor. Next, the surface-emitting laser 200 is concretely described.

The surface-emitting laser 200 is formed from a lower DBR 211, an active layer 212, an upper DBR 213, a lens layer 215, an upper electrode 216, an embedding layer 217, an oxidation constricting layer 218, and the multilayer reflection film 219. Here, the lower DBR 211 can be formed in the same manner as the lower DBR 111 of the first embodiment. The active layer 212 is disposed on an upper layer of the lower DBR 211, and can be formed in the same manner as the active layer 112. The upper DBR 213 is disposed on an upper layer of the active layer 212, and can be formed in the same manner as the upper DBR 113. The lens layer 215 is disposed on an upper layer of the upper DBR 213, has a convex lens shape, and can be formed in the same manner as the lens layer 115. The oxidation constricting layer 218 is formed inside the upper DBR 213, and can be formed in the same manner as the oxidation constricting layer 118.

The multilayer reflection film 219 is formed from semiconductor, and is disposed on an upper surface of the lens layer 215. Concretely, for example, the multilayer reflection film 219 is formed from a semiconductor multilayer reflection film composed of 10 cycles of GaAs/AlGaAs layers. The embedding layer 217 is arranged in a manner to embed the circumference of the columnar section composed of the active layer 212, the upper DBR 213, the lens layer 215 and the multilayer reflection film 219. The constituent material of the embedding layer 217 can be the same constituent material of the embedding layer 117. The upper electrode 216 has a ring shape, disposed in an outer circumference neighboring portion of the multilayer reflection film 219, and electrically connected to the outer circumference neighboring portion. Also, a portion of the upper electrode 216 is disposed on the embedding layer 217.

According to the above, in the surface-emitting laser 200 of the present embodiment, the transverse mode can be more effectively controlled and the laser emission angle can be reduced by the multilayer reflection film 219, like the surface-emitting laser 100 of the first embodiment. Also, in accordance with the present embodiment, the lens layer 215 is formed from semiconductor, and therefore the lens layer 215 can be readily formed into a lens shape, and a surface-emitting laser 200 that exhibits a high performance and can be readily manufactured can be provided. Also, in accordance with the present embodiment, because the multilayer reflection film 219 is formed from semiconductor, there can be provided a surface-emitting laser 200 in which a contact between the multilayer reflection film 219 and the upper electrode 216 can be readily made, and therefore can be readily manufactured.

Next, a method for manufacturing the surface-emitting laser 200 is described. First, like the first step to the fifth step of the first embodiment, a lower DBR 211, an active layer 212, an upper DBR 213, a lens layer 215 and an oxidation constricting layer 218 are formed. Then, a multilayer reflection film 219 composed of semiconductor is formed on an upper layer of the lens layer 215. Next, an embedding layer 217 is formed in a manner to embed the circumference of a columnar section composed of the active layer 212, the upper DBR 213, the lens layer 215 and the multilayer reflection film 219. Then, an upper electrode 216 that electrically connects to an outer circumference neighboring portion of the multilayer reflection film 219 is formed, whereby the surface-emitting laser 200 shown in FIG. 4 is completed.

### THIRD EMBODIMENT

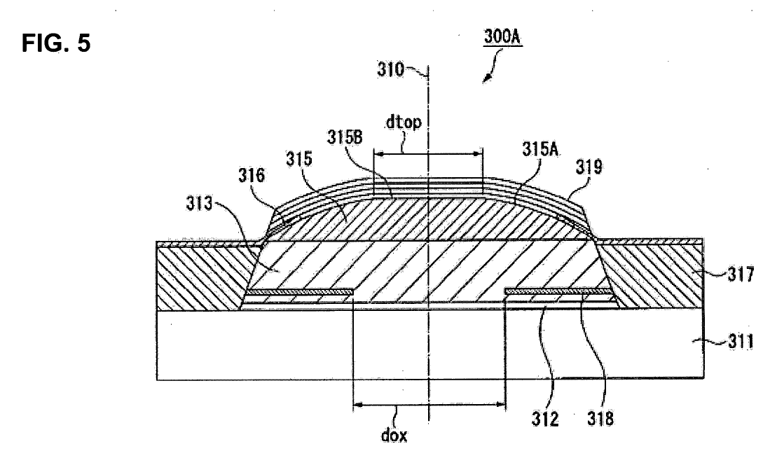

FIG. 5 is a schematic cross-sectional view showing one example of a surface-emitting laser in accordance with a third embodiment of the present invention. A main difference between the surface-emitting laser 300A of the present embodiment and the surface-emitting laser 100 of the first embodiment is that, though a lens layer 315 has a convex lens shape, an apex portion 315B of the convex lens shape is flat. Next, the surface-emitting laser 300A is concretely described.

The surface-emitting laser 300A is formed from a lower DBR 311, an active layer 312, an upper DBR 313, a lens layer 315, an upper electrode 316, an embedding layer 317, an oxidation constricting layer 318, and a multilayer reflection film 319. Here, the lower DBR 311 can be formed in the same manner as the lower DBR 111 of the first embodiment. The active layer 312 is disposed on an upper layer of the lower DBR 311, and can be formed in the same manner as the active layer 112. The upper DBR 313 is disposed on an upper layer of the active layer 312, and can be formed in the same manner as the upper DBR 113. The lens layer 315 is disposed on an upper layer of the upper DBR 313, and can be formed in the same manner as the lens layer 115 though its shape is different from the lens layer 115. The oxidation constricting layer 318 is formed inside the upper DBR 313, and can be formed in the same manner as the oxidation constricting layer 118. Furthermore, an oxidation constricting aperture in the oxidation constricting layer 318, in other words, a flow area in which a current flows, has a diameter dₒₓ. The multilayer reflection film 319 is disposed on an upper layer of the lens layer 315, and can be formed in the same manner as the multilayer reflection film 119.

The lens layer 315 is formed in a convex lens shape having a flat apex portion, as shown in FIG. 5. In other words, the lens layer 315 includes a curved surface portion 315A defining a convex lens, and a flat apex portion 315B. The center of the apex portion 315B is disposed on the center axis 310 of the surface-emitting laser 300A. Further, the plane configuration of the apex portion 315B is in a circular shape, and the plane configuration of the curved surface portion 315A is in a ring shape. The flat apex portion 315B has a size with a diameter being dₜₒₚ. It is noted that the apex portion 315B may preferably be as small as possible, and may preferably have a relation of “Diameter dₜₒₚ<Diameter dₒₓ.”

In view of the above, according to the surface-emitting laser 300A of the present embodiment, the lens layer 315 has the apex portion 315B that is flat, such that a processing treatment such as etching does not need to be conducted for the apex portion 315B when the lens layer 315 is formed. Accordingly, in the surface-emitting laser 300A, the thickness of the lens layer 315 at the center axis 310 of the resonator can be readily set with a high accuracy. Accordingly, in the surface-emitting laser 300A, the index of reflection of the resonator at its center axis 310, which is most important for the surface-emitting laser to exhibit its functions, can be highly accurately set to a desired value. Accordingly, with the surface-emitting laser 300A, the basic laser characteristics such as the threshold value, efficiency and the like can be readily and excellently obtained.

Also, in the surface-emitting laser 300A, light emitted from portions of the resonator removed from its center axis 310 can receive the concave surface mirror effect of the multilayer reflection film that is laminated on the upper layer of the curved surface portion 315A of the lens layer 315. Therefore, with the surface-emitting laser 300A, a sufficient beam re-shaping effect as a whole can be obtained, and the laser emission angle can be sufficiently made smaller.

### FOURTH EMBODIMENT

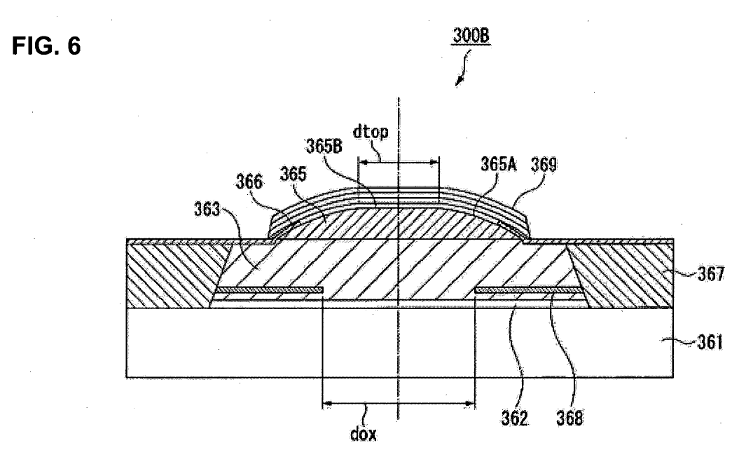

FIG. 6 is a schematic cross-sectional view showing one example of a surface-emitting laser in accordance with a fourth embodiment of the present invention. A main difference between the surface-emitting laser 300B of the present embodiment and the surface-emitting laser 100 of the first embodiment is that a bottom surface of a convex lens shape of a lens layer 365 is smaller than an upper surface of an upper DBR 363. In other words, the bottom surface of the lens layer 365 is smaller than an upper surface of a columnar section (an active layer 362 and an upper DBR 363) composing a part of the resonator. However, the lens layer 365 has a shape that is similar to that of the lens layer 315 of the third embodiment, and includes a curved surface portion 365A defining a convex lens, and a flat apex portion 365B. Next, the surface-emitting laser 300B is concretely described.

The surface-emitting laser 300B is formed from a lower DBR 361, an active layer 362, the upper DBR 363, the lens layer 365, an upper electrode 366, an embedding layer 367, an oxidation constricting layer 368, and a multilayer reflection film 369. Here, the lower DBR 361 can be formed in the same manner as the lower DBR 111 of the first embodiment. The active layer 362 can be formed in the same manner as the active layer 112. The upper DBR 363 can be formed in the same manner as the upper DBR 113. The upper electrode 366 can be formed in the same manner as the upper electrode 116 though its shape is different from the upper electrode 116. The upper electrode 366 has a ring shape, and is electrically connected to an outer circumference neighboring portion of the lens layer 365. The embedding layer 367 can be formed in the same manner as the embedding layer 117. The oxidation constricting layer 368 can be formed in the same manner as the oxidation constricting layer 118. The multilayer reflection film 369 is disposed in a manner to cover an exposed portion of the lens layer 365, and can be formed in the same manner as the multilayer reflection film 119. Also, the multilayer reflection film 369 may be disposed to cover also a portion of the upper electrode 366.

According to the above, in the surface-emitting laser 300B in accordance with the present embodiment, the lens shaped portion defined by the lens layer 365 is provided on a portion of the upper surface of the upper DBR 363, such that the convex lens shape can be formed with a small curvature. Accordingly, in the surface-emitting laser 300B, the effect of reducing the laser emission angle by the multilayer reflection film 369 disposed on an upper layer of the lens layer 365 can be enhanced.

Electronic Apparatus

Examples of electronic apparatuses equipped with the surface-emitting laser of the embodiments described above are described.

The surface-emitting lasers of the present embodiments may be applied to optical fiber communications modules, optical interconnections that transmit and receive optical signals within an apparatus or a substrate, optical disk heads, laser printers, laser beam projectors, laser beam scanners, linear encoders, rotary encoders, displacement sensors, pressure sensors, gas sensors, liquid sensors, blood flow sensors, optical inter-couplers, parallel optical processors, and the like.

The technical scope of the present invention is not limited to the above-described embodiments, and various kinds of modifications can be made within the scope that does not deviate from the subject matter of the present invention. The concrete materials, layered structures, and the like enumerated in the embodiments are only part of examples and can be appropriately modified.

What is claimed is:

1. A surface-emitting laser comprising:
a lens layer formed from semiconductor having a lens shape, that is a component of a resonator of the surface-emitting laser; and
a multilayer reflection film disposed on an upper layer of the lens layer.

2. A surface-emitting laser according to claim 1, wherein the multilayer reflection film is formed from multilayer dielectric films.

3. A surface-emitting laser according to claim 1, wherein the multilayer reflection film is formed from multilayer semiconductor films.

4. A surface-emitting laser according to claim 1, wherein
the lens layer is disposed on an upper layer of the upper DBR and has a convex lens shape,
on an outer circumference neighboring portion of the lens layer, an upper electrode that is electrically connected to the outer circumference neighboring portion is disposed, and
the multilayer reflection film is disposed to cover an exposed portion of the lens layer and at least a portion of the upper electrode.

5. A surface-emitting laser according to claim 3, wherein
the lens layer is disposed on an upper layer of the upper DBR and has a convex lens shape,
the multilayer reflection film is disposed on an upper layer of the lens layer, and
on an outer circumference neighboring portion of the multilayer reflection film, an upper electrode that is electrically connected to the outer circumference neighboring portion is disposed.

6. A surface-emitting laser according to claim 1, wherein the lens layer is in a convex lens shape having a flat apex portion.

7. A surface-emitting laser according to claim 1, wherein the lens layer has a convex lens shape, and a bottom surface of the convex lens shape is smaller than an upper surface of a columnar section composing a part of the resonator of the surface-emitting laser.

8. A surface-emitting laser comprising:
a lower DBR defining a distributed reflection type multilayer mirror;
an active layer;
a current aperture layer defining a flow area of a current;
an upper DBR defining a distributed reflection type multilayer mirror;
a lens layer formed from semiconductor having a lens shape; and
a multilayer reflection film disposed on an upper layer of the lens layer.

9. A surface-emitting laser according to claim 8, wherein the multilayer reflection film is formed from multilayer dielectric films.

10. A surface-emitting laser according to claim 8, wherein the multilayer reflection film is formed from multilayer semiconductor films.

11. A surface-emitting laser according to claim 8, wherein
the lens layer is disposed on an upper layer of the upper DBR and has a convex lens shape,
on an outer circumference neighboring portion of the lens layer, an upper electrode that is electrically connected to the outer circumference neighboring portion is disposed, and
the multilayer reflection film is disposed to cover an exposed portion of the lens layer and at least a portion of the upper electrode.

12. A surface-emitting laser according to claim 10, wherein
the lens layer is disposed on an upper layer of the upper DBR and has a convex lens shape,
the multilayer reflection film is disposed on an upper layer of the lens layer, and
on an outer circumference neighboring portion of the multilayer reflection film, an upper electrode that is electrically connected to the outer circumference neighboring portion is disposed.

13. A surface-emitting laser according to claim 8, wherein the lens layer is in a convex lens shape having a flat apex portion.

14. A surface-emitting laser according to claim 8, wherein the lens layer has a convex lens shape, and a bottom surface of the convex lens shape is smaller than an upper surface of a columnar section composing a part of the resonator of the surface-emitting laser.

15. A method for manufacturing a surface-emitting laser comprising:
forming at least a plurality of semiconductor layers on a semiconductor substrate to form a semiconductor laminated body that is a component of a resonator of the surface-emitting laser;
forming a resist layer having a lens shape on the semiconductor laminated body;
forming a columnar section that becomes a part of the resonator and bringing an upper surface of the columnar section in a lens shape in relief by conducting an etching treatment using the resist layer as a mask; and
forming a multilayer reflection film on an upper surface of the columnar section in a lens shape.

16. A method for manufacturing a surface-emitting laser according to claim 15, wherein
an upper electrode in a ring shape is formed on an outer circumference neighboring portion of the upper surface of the columnar section in a lens shape formed by the etching treatment, and then
the multilayer reflection film is formed to cover at least an exposed portion in the upper surface of the columnar section in a lens shape.

17. A method for manufacturing a surface-emitting laser according to claim 15, wherein, after the multilayer reflection film is formed, an upper electrode in a ring shape is formed on an outer circumference neighboring portion of an upper surface of the multilayer reflection film.

18. A method for manufacturing a surface-emitting laser according to claim 15 wherein the etching treatment includes
dry etching with a high selection ratio that hardly etches the resist layer but etches the semiconductor laminated body to thereby form the columnar section, and
dry etching with a low selection ratio that etches the resist layer and the semiconductor laminated body at the same time to thereby form an upper surface of the columnar section in a lens shape in relief.

19. A method for manufacturing a surface-emitting laser according to claim 15, wherein the etching treatment is to form the columnar section that becomes a part of the resonator and the upper surface of the columnar section including the resist layer in a lens shape in relief, and including, after the etching treatment, a process to remove the resist layer remaining on the apex portion of the lens shape.
